(19) United States
(12) Patent Application Publication
(10) Pub. No.: US 2007/0249503 A1
(43) Pub. Date: Oct. 25, 2007

(54) Wireless sensor network with superconducting nodes

(75) Inventors: Kartik B. Ariyur, Minnetonka, MN (US); Anoop K. Mathur, Shoreview, MN (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International Inc.

(21) Appl. No.: 11/409,849

(22) Filed: Apr. 24, 2006

(51) Int. Cl. H01L 39/00; G08B 1/08

(52) U.S. Cl. 505/150; 340/539.22

(57) ABSTRACT

A node in a wireless sensor network has a receiver that is at least partially implemented in high temperature superconductor circuitry. In one embodiment, band pass filters of the receiver are implemented in high temperature superconducting circuitry. In one embodiment, a cryo-cooler is coupled to a passage for providing coolant to the receiver such that the receiver is cooled at or below the superconducting temperature of its circuit elements.

### BACKGROUND

Wireless sensor networks are formed of wireless leaf nodes having sensors. The wireless leaf nodes transmit data to infrastructure nodes, which may be line powered, or have a more robust power source. The leaf nodes are usually powered by batteries. The batteries have a useful life that is limited, and is a function of the transmission power of the sensor coupled with the number of times that a sensor needs to transmit data. In some sensor networks, transmissions of data from a sensor may collide with transmissions from other sensors. The sensor may then retransmit the data additional times in order for the data to be properly received. Transmissions at high power levels and retransmissions can significantly shorten the battery life, and cause the need for maintenance to be performed to replace the batteries. There is a need to extend the battery life of wireless leaf nodes to reduce maintenance costs. There is also the need to install sensor networks where space is constrained. Moreover, in some areas, wireless signal strength is extremely small because of the large areas of metal surfaces which act as antennas. Finally, if wired systems are to be replaced by wireless systems, reliability of wireless transmission of information should be ensured.

### SUMMARY

A node in a wireless sensor network has a receiver that is at least partially implemented in high temperature superconductor circuitry. In one embodiment, a cryo-cooler is coupled to a passage for providing coolant to the receiver such that the receiver filters are cooled to superconducting temperature or below. Other portions of the receiver electronics may also be cooled and may be designed to take advantage of the low operating temperature.

### BRIEF DESCRIPTION OF THE DRAWINGS

FIG. 1 is a block diagram of a wireless network having superconducting infrastructure nodes according to an example embodiment.

FIG. 2 is a block diagram of a superconducting and super cooled node according to an example embodiment.

FIG. 3 is a block schematic diagram of a receiver portion of a superconducting node according to an example embodiment.

FIG. 4 is a block cross section diagram of a superconducting node according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description is, therefore, not to be taken in a limited sense, and the scope of the present invention is defined by the appended claims.

The functions or algorithms described herein are implemented in software or a combination of software and human implemented procedures in one embodiment. The software may consist of computer executable instructions stored on computer readable media such as memory or other type of storage devices. The term “computer readable media” is also used to represent any means by which the computer readable instructions may be received by the computer, such as by different forms of wireless transmissions. Further, such functions correspond to modules, which are software, hardware, firmware or any combination thereof. Multiple functions are performed in one or more modules as desired, and the embodiments described are merely examples. The software is executed on a digital signal processor, ASIC, microprocessor, or other type of processor operating on a computer system, such as a personal computer, server or other computer system.

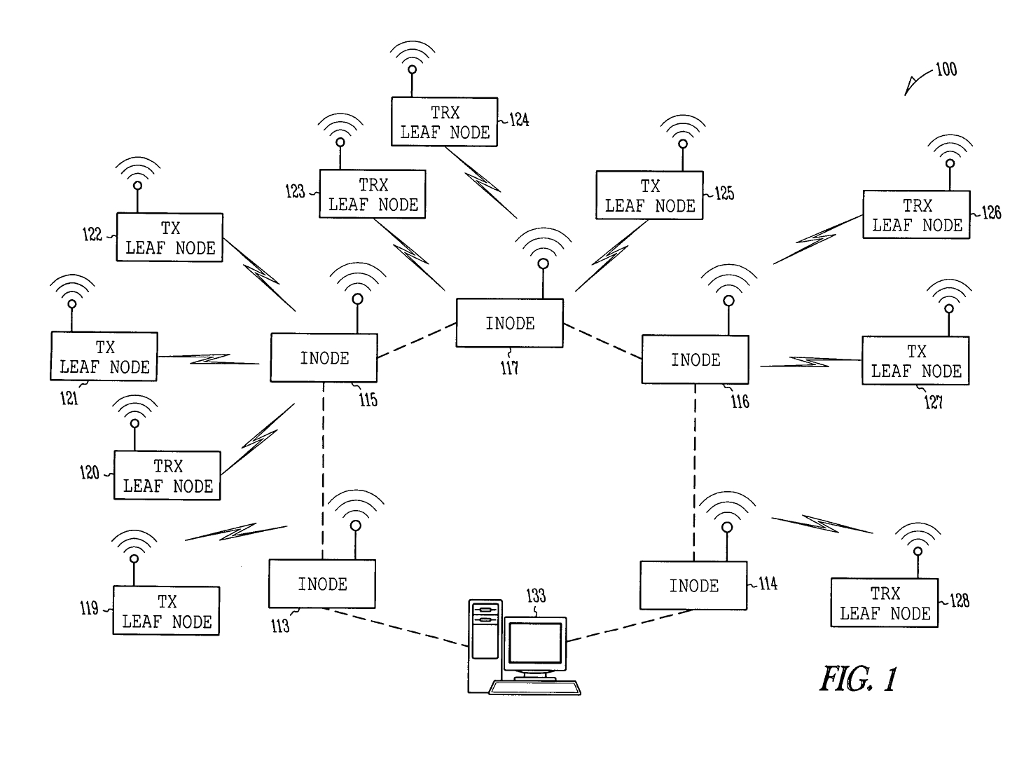

Wireless sensors and actuators have become very attractive due to ease of installation and wiring and labor cost savings. In one embodiment, wireless communication systems such as the system 100 illustrated in block diagram form in FIG. 1 allow the deployment of wireless devices in desired locations and may increase overall coverage area.

Infrastructure nodes in one embodiment are transceivers that may be placed in various locations such as in an industrial plant or in a field to cover areas and the infrastructure nodes are linked to each other via wireless or wired links. In one embodiment, infrastructure nodes (Inodes) may capture wireless communications from multiple leaf nodes that are located within communication range of the infrastructure nodes. The leaf nodes may be internally or battery powered wireless sensors and actuators. Various communication protocols may be implemented allowing wireless communications between the nodes. In one embodiment, frequency spreading/frequency hopping protocols may be used.

In one embodiment, there are at least two types of leaf nodes. One type of leaf node is referred to as a TX leaf node indicated at 119, and is communicating with Inode 113. TX leaf node 119 is a transmit only leaf node, which transmits signals to the Inode 113. In one embodiment, it may transmit a signal with the same information several times to ensure that it has been received. Since it does not have a receiver, it cannot receive any sort of acknowledgement from Inode 113.

A second type of leaf node 120 is referred to as a TRX leaf node, because it contains a transceiver, allowing two way communication between Inode 115. In one embodiment, the communication connection is wireless, and allows the Inode to receive data from the TRX leaf node, and allows the TRX leaf node to receive acknowledgements from the Inode.

In FIG. 1, a plurality of Inodes and various leaf nodes are shown. In further embodiments, the numbers of such nodes may be greatly varied. Example system 100 has Inode 113 coupled to TX leaf node 119, Inode 115 coupled to TRX leaf node 120, and TX leaf nodes 121 and 122. Inode 117 is coupled to TRX leaf nodes 123 and 124 and TX leaf node 125. Inode 116 is coupled to TRX leaf node 126 and TX leaf node 127, and Inode 115 is coupled to TRX leaf node 128.

In one embodiment, infrastructure nodes forward sensor data from a leaf node to data recipient hardware, such as a control room, central station, and/or a computer 133. Infrastructure nodes 113 and 114 may be gateway nodes that are hard-wired to a bus or may be wirelessly connected. There may be just one infrastructure gateway node or more than two such nodes.

Infrastructure nodes 115, 116 and 117 may be line powered and capable of significant wireless range and good reliability in the delivery of information. However, the desired wiring cost savings and flexibility of placement of sensors (leaf nodes) makes it desirable to use wireless sensors like leaf nodes 119-128. These leaf nodes may be low power, small size, low cost and low complexity radios that operate with battery power.

FIG. 2 is a simplified block diagram of an infrastructure node 200 with selected portions implemented with superconductors and correspondingly cooled. Infrastructure node 200 includes a processor 210 coupled to a transceiver 215, which in turn is coupled to an antenna 220 that receives and transmits signals. A cryo-cooler 225 provides cooling for the infrastructure node 200. In one embodiment, the infrastructure node may be implemented on a circuit board or other component supporting device. The cryo-cooler 225 provides cooling, such as by circulation of a coolant proximate selected components, such as underneath the circuit board. In one embodiment, the circuit board is packaged within an insulative container to ensure that the components are cooled to a temperature low enough for superconductivity.

In one embodiment, the coolant is liquid nitrogen, which is sufficient to cool the components for super conducting operation of high temperature super conductor components. The cryo-cooler liquefies nitrogen to produce the liquid nitrogen. In one embodiment, the antenna and transceiver or transmitter are cooled. In further embodiments, all the components of the infrastructure node may be cooled.

Cryo-coolers are commercially available in a variety of sizes. High temperature superconducting circuitry is also commercially available. Honeywell Hymatic Stirling cryo-coolers may have a fairly small footprint. In one embodiment, a Hymatic cryo-cooler uses an electric powered compressor, and operates on the well-proven ‘Oxford’ principles of spiral flexure springs and non-contacting clearance seals. The cooler is a compact moving piston design, with the piston and cylinder located within a core of a magnetic circuit of a moving coil motor. One compressor has been designed to operate with a nominal 100 Watts of input power with an additional 50% input power margin. An example compressor has an overall length of 226 mm, with end caps 57 mm in diameter and a mass of 2.45 kg. Coolers are available in many different sizes, and may be as small as the size of a United States quarter.

Several benefits of using super conducting components may be obtained in various embodiments. Many wireless sensor networks are used in high noise environments, such as refineries or other environments having significant metal structures which interfere with wireless transmissions. Having the circuitry cooled results in minimizing thermal noise levels, which can interfere with reception and processing of signals. Consistent with super conducting circuitry is an increase in accuracy of signal processing, allowing a larger number of leaf nodes to be serviced by a fewer number of infrastructure nodes. Since infrastructure nodes are generally larger than leaf nodes, and space in the deployment area may be limited, the ability to use a smaller number of infrastructure nodes can help conserve space.

The reduction of thermal noise and increased sensitivity of the infrastructure nodes to signals transmitted by the leaf nodes allows lower power to be used by the leaf nodes in transmitting. It may also reduce the number of retransmissions required, since the infrastructure node is more likely to receive low power signals and differentiate them from other signals, including noise. Thus, TX nodes may be programmed to transmit a fewer number of times, or their transmit power may be reduced. TRX nodes may transmit at lower power, and have a higher likelihood of receiving an acknowledgement at the lower transmit power. This helps conserve the battery life in leaf nodes, resulting in lower maintenance costs. Alternatively, leaf nodes may be placed further from the infrastructure nodes, and the transmit power adjusted accordingly. This feature allows the use of fewer infrastructure nodes, conserving space.

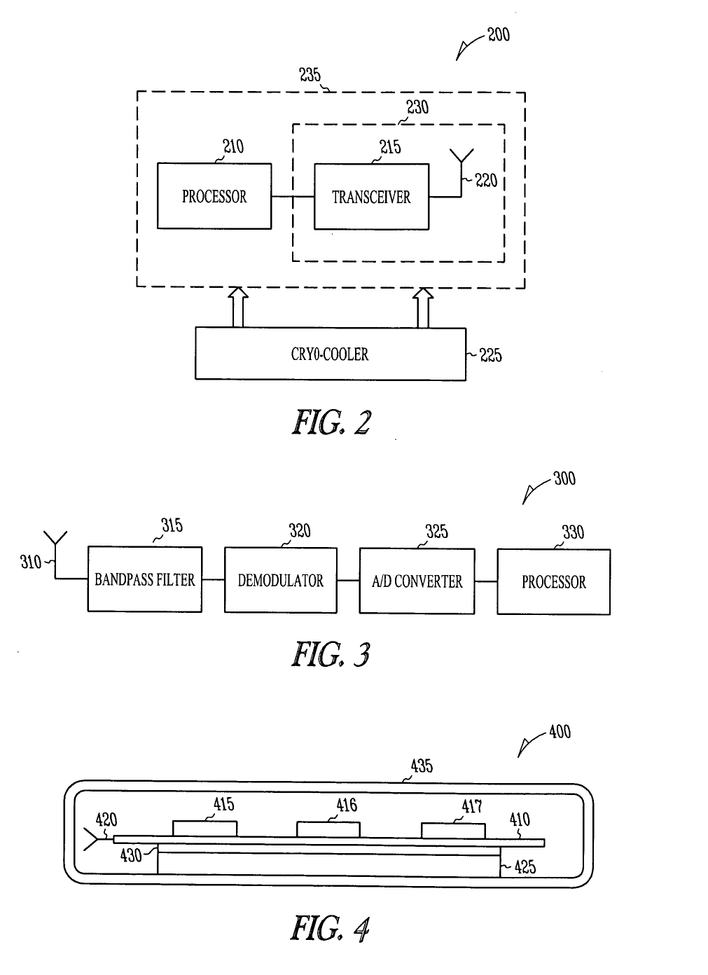

FIG. 3 illustrates a reception path 300 for a leaf node or infrastructure node that is constructed of high temperature super conducting circuitry and is correspondingly cooled. The difference in this circuit from traditional node circuitry for nodes is the minimal use if any, of amplifiers. Traditional node circuitry utilizes an amplifier of the signal received from an antenna 310. Such received signals are traditionally amplified and provided to a bandpass filter 315, amplified, and then demodulated at 320, perhaps amplified again, and converted at A/D converter 325. The converted signal is then provided to a processor 330 or other processing circuitry. Thus, as shown, a cryo-cooled high temperature super conducting node may not require additional amplifiers, thus, further cutting down on the circuitry required and cutting down on power required, further conserving battery life, should an infrastructure node be powered by a battery. Such a battery powered infrastructure node may be used in applications where infrastructure power is not readily available, and it is desired to maximize information that may be gathered from sensors.

Because of the use of high temperature superconducting electronics and signal processing for the wireless nodes, the circuits work at very low signal to noise ratio, and the filter 315 may be a very sharp high order filter. This further increases the number of frequencies that may be used to carry signals within a bandwidth. The spectral gap between frequencies used may be reduced.

An example cooled node is illustrated at 400 in FIG. 4. Many other configurations of coolant delivery and packaging may be used, and this is provided as a simple example. A circuit board 410 is populated with modules 415, 416, 417 and an antenna 420. More or fewer modules may be used to implement the functions of an infrastructure node in high temperature superconducting electronics, such as those available from Superconductor Technologies Inc., headquartered in Santa Barbara, Calif., US (http://www.suptech.com/), or from ISCO International, Inc. of headquartered in Illinois (www.iscointl.com).

Coolant, such as liquid nitrogen is delivered via a duct 425, which may be coupled directly to the circuit board or circuit carrier/substrate, or separated by a spacer 430. In one embodiment, the coolant is located proximate the circuitry to ensure it operates in a superconducting mode. An insulating container is represented at 435 and provides insulation to keep the circuitry in a superconducting state. As appreciated by those of skill in the art, the actual insulation packaging may be more complex, with additional layers and insulating technologies.

The Abstract is provided to comply with 37 C.F.R. §1.72(b) to allow the reader to quickly ascertain the nature and gist of the technical disclosure. The Abstract is submitted with the understanding that it will not be used to interpret or limit the scope or meaning of the claims.

1. A node in a wireless sensor network, the node comprising:
a receiver having a portion implemented in high temperature superconductor circuitry;
a cryo-cooler; and
a passage providing coolant from the cryo-cooler to the receiver such that the portion of the receiver implemented in high temperature superconductor circuitry is cooled at or below its superconducting temperature.

2. The node of claim 1 wherein the receiver comprises an antenna, a bandpass filter and a demodulator, wherein at least the bandpass filter is implemented in high temperature superconductor circuitry.

3. The node of claim 2 and further comprising an A/D converter coupled to the bandpass filter and a processor coupled to the A/D converter.

4. The node of claim 1 wherein the coolant comprises liquid nitrogen.

5. The node of claim 1 wherein the node further comprises means for providing power to the circuitry.

6. The node of claim 1 and further comprising an insulating container containing the circuitry.

7. The node of claim 1 wherein the node comprises a line powered infrastructure node.

8. An infrastructure node for a wireless sensor network, the infrastructure node comprising:
a high temperature superconducting receiver coupled to the processor; and
an antenna coupled to the receiver.

9. The infrastructure node of claim 8 and further comprising an insulating container surrounding the receiver, and a duct for providing liquid nitrogen coolant.

10. An infrastructure node for a wireless sensor network, the infrastructure node comprising:
a processor;
a transceiver having high temperature superconducting bandpass filters coupled to the processor; and
an antenna coupled to the transceiver.

11. The infrastructure node of claim 10 wherein the processor comprises a high temperature superconducting processor, and the antenna comprises a high temperature superconducting antenna.

12. The infrastructure node of claim 10 and further comprising coolant ducts proximate the high temperature superconducting bandpass filters.

13. The infrastructure node of claim 12 wherein the coolant ducts contain liquid nitrogen.

14. The infrastructure node of claim 13 and further comprising an insulating container containing the circuitry.

15. The infrastructure node of claim 14 wherein the coolant ducts are disposed at least partially within the insulating container.

16. The infrastructure node of claim 14 wherein the antenna is within the insulating container.

17. The infrastructure node of claim 10 wherein the infrastructure node is line powered.

18. The infrastructure node of claim 10 wherein the high temperature superconducting bandpass filters are coupled to the antenna and coupled to a demodulator.

19. The infrastructure node of claim 10 and further comprising a processor coupled to the transceiver.

20. The infrastructure node of claim 19 wherein the processor is formed of high temperature superconducting circuitry or other low temperature electronic circuitry.
